(19) United States
(12) Patent Application Publication
(10) Pub. No.: US 2004/0017245 A1
(43) Pub. Date: Jan. 29, 2004

(54) Gate driving circuit in power module

(75) Inventor: Kouichi Mochizuki, Fukuoka (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/614,032

(22) Filed: Jul. 8, 2003

(30) Foreign Application Priority Data
Jul. 26, 2002 (JP) 2002-218674

(51) Int. Cl. H03K 17/60

(52) U.S. Cl. 327/432

(57) ABSTRACT

A coil section 18 formed as a portion of a gate wire 16 of an IGBT 10 is wound around and electrically insulated from a main current circuit wire 17. One end of the coil section is connected to a gate terminal 12, while the other end thereof is connected to a gate bias power source 15 to induce an electromotive force based only on a main current of the IGBT. Thus, a gate bias is controlled by utilizing the electromotive force produced on the coil section according to a time variation of the main current, thereby suppressing an over-current in a power module.

### BACKGROUND OF THE INVENTION

1. Field of the Invention

The present invention relates to a gate driving circuit in a power module, and more particularly to a gate driving circuit in a power module using a power switching device such as an insulated gate bipolar transistor (hereinafter referred to as “IGBT”), wherein a gate bias is changed on real time according to a time variation in main current, so that an over-current is suppressed when a load is short-circuited, improving a tolerance of a power module.

2. Description of the Related Art

Power electronics such as a motor control circuit for driving a motor or the like generally utilize, as a switching device, a power semiconductor device such as an IGBT or the like due to its characteristic in an area where a rated voltage is 300 V or more. In many cases, a power semiconductor device such as an IGBT, diode or the like are mounted on one package to be used as a power module for an electric power conversion system.

A power switching device generally controls turning-on and turning-off of high voltage and high electric current at a high switching frequency, and it is desired to have a reduced switching time and reduced switching loss. However, development of a switching device to have a higher switching speed increases a time variation in current (i.e., di/dt) at a time of turning-on and turning-off in a switching device having a high response speed for turning-on and turning-off. As a result, a surge voltage may be undesirably produced to cause a breakdown or malfunction of a device.

Specifically, in the case where the IGBT used as a switching device performs on/off operation, a time variation in voltage (dv/dt) of an extremely high degree is produced at a time of a reverse recovery of a flywheel diode (FWD) connected in parallel to a device located in a turned-off side. Due to this time variation in voltage dv/dt, a current flows so as to charge a junction capacitance between a collector and a gate, which increases a voltage between the gate and the emitter to a degree not less than a gate threshold value, resulting in that a malfunction and a series short-circuit of a switching device may be caused.

Further, in the case where a switching device is incorporated to be used in various apparatuses, the performance characteristic such as turning-on speed of the switching device must be adopted to the operating condition of the apparatus to which the device is applied.

FIG. 5 shows an example of a circuit configuration of a conventional gate driving circuit in a power module. In the gate driving circuit shown in the figure, numeral 50 denotes an IGBT, 51 an emitter terminal that is one of main terminals of the IGBT, 52 a gate terminal to which a control signal is inputted, 53 a collector terminal that is one of main terminals of the IGBT, 54 a lead wire that is connected between the emitter terminal side and a gate bias power source 55 and serves as a reference of the gate bias, 56 a gate wire having a gate current suppressing resistor R_{G}, and 57 a flywheel diode (FWD) connected in parallel between the collector and the emitter.

In a conventional power module as shown in FIG. 5, a potential on the side of the emitter terminal 51 of the IGBT 50 is set as a reference potential. A bias voltage with respect to the reference potential is applied from the gate bias power source 55 to the gate terminal 52 via the gate current suppressing resistor R_{G} of the gate wire 56. Thus, charges are accumulated and emitted on and from a gate oxide film (not shown) of the IGBT 50, thereby performing on/off control of the IGBT.

Conventionally, as described above, the time variation di/dt in main current flowing through the emitter terminal 51 side has been mainly determined by the resistance value of the gate current suppressing resistor R_{G}. This configuration reduces on-voltage, but entails a problem of increasing a gate capacitance and short-circuit current. Specifically, even if the time variation in main current is great, for example, when a load is short-circuited in the power module, the gate control is performed in the same manner as that in a normal condition. As a result, the main current flows through the emitter terminal side in accordance with its transfer characteristic in the active area of the IGBT. Accordingly, when a calorific value calculated as a time integration of a product of the main current (I_{C}) and the supply voltage (V_{CE}) exceeds a limit of a heat tolerance value of the IGBT, there arises a problem that the IGBT itself of the power module is led to thermal breakdown.

### SUMMARY OF THE INVENTION

The present invention has been made to solve the above-mentioned problems, and has an object to provide a gate driving circuit that can control a gate capacitance and short-circuit current, as well as can suppress an over-current at a time of short-circuiting a load to a power module using an IGBT to thereby prevent a thermal breakdown of the IGBT in the power module.

In order to attain the object mentioned above, a first aspect of the present invention provides a gate driving circuit which performs a gate driving control by supplying a bias voltage from a gate bias power source to a gate terminal of a power switching device via a gate wire. The gate driving circuit includes: a main current circuit wire that connects an emitter terminal of the power switching device to an external load; and an electromotive force inducing coil section formed of a portion of the gate wire which is wound around a part of the main current circuit wire in an electrically insulated condition.

In this arrangement, one end of the electromotive force inducing coil section is connected to the gate terminal, while the other end thereof is connected to the gate bias power source via a gate driving current suppressing resistor. The electromotive force inducing coil section induces an induction electromotive force based only on a main current of the power switching device flowing on the main current circuit wire.

By this arrangement, since the gate bias is controlled by using an electromotive force of the coil according to a time variation of the main current, the time variation of the main current can be suppressed on real time when such as an external load is short-circuited. Therefore, self-heating of the IGBT can be suppressed at a time of the short-circuit, thereby improving a short-circuit tolerance. Moreover, since the main current circuit wire passes through the coil section, the electromotive force produced in the coil is not affected by a distance between the main current circuit wire and the coil, but is determined by the number of turns of the coil and its diameter, thereby obtaining a stabilized electromotive force.

A second aspect of the present invention provides a gate driving circuit in a power module which is mounted on a power switching device chip. The gate driving circuit includes: a gate pad to which a gate wire is connected for supplying a bias voltage from a gate bias power source to a gate terminal of the power switching device; an emitter pad to which a main current circuit wire is connected for connecting an emitter terminal of the power switching device to an external load; and an electromotive force inducing section formed of a portion of the gate wire which is wound around the emitter pad in an electrically insulated condition.

In this arrangement, one end of the electromotive force inducing section is connected to the gate terminal, while the other end thereof is connected to the gate pad, and the electromotive force inducing section induces the induction electromotive force based only on a main current of the power switching device flowing on the main current circuit wire.

By this arrangement, the time variation of the main current can be suppressed every IGBT chip, and therefore the short-circuit tolerance can be enhanced in the case of mounting parallel chips on the module.

### BRIEF DESCRIPTION OF THE DRAWINGS

These and other objects and features of the present invention will be readily understood from the following detailed description taken in conjunction with preferred embodiments thereof with reference to the accompanying drawings, in which:

FIG. 1 is a circuit diagram of a gate driving circuit according to an embodiment 1 of the present invention;

FIG. 2 is a waveform chart showing performance characteristics relating to a time variation compared between the embodiment 1 of the present invention and a conventional circuit;

FIG. 3 is a plan view schematically showing a configuration of a gate driving circuit in a power module according to an embodiment 2 of the present invention;

FIG. 4 is a plan view schematically showing a configuration of a gate driving circuit in a power module according to an embodiment 3 of the present invention; and

FIG. 5 is a circuit diagram of a conventional gate driving circuit in a power module.

### DETAILED DESCRIPTION OF THE PREFERRED EMBODIMENTS

According to the present invention, a gate driving circuit in a power module has an IGBT mounted thereon and is used in a motor control circuit or the like. The gate driving circuit has a coil section incorporated in a portion of a gate wire so that a bias voltage is applied to a gate of the IGBT through the coil section. The coil section is wound around a main current circuit wire so as to be electrically insulated therefrom, and one end of the coil section is connected to a gate terminal of the IGBT, while the other end thereof is connected to a gate bias power source via a gate driving current suppressing resistor on the gate wire.

Thus, in a configuration of the gate driving circuit, the coil section is incorporated in the gate wire such that the coil section is wound around the main current circuit wire and positioned on the emitter terminal side of the main current circuit wire in a manner such that the coil is electrically insulated from the main current circuit wire.

By this arrangement, the time variation in the main current at a time of short-circuiting a load to the power module is suppressed by converting the variation of the main current into an induced voltage to be produced on the coil section so that the gate bias is varied on real time. By this configuration, the over-current at a time of short-circuiting a load to the power module is suppressed so that the tolerance of the power module is improved, thereby preventing a thermal breakdown of the IGBT in the power module.

Further, the IGBT has a flywheel diode connected between the collector and the emitter, wherein a junction point of a cathode terminal side wire of the flywheel diode and the main current circuit wire is located at a position between the electromotive force inducing coil section and the external load on the main current circuit wire, i.e., outer side with respect to the winding position of the coil section.

Thus, the junction point on the wire at the side of the cathode terminal of the flywheel diode (FWD) and the main current circuit wire is positioned at the side opposite to the emitter terminal with respect to the winding position of the coil section, so that the induced electromotive force produced on the coil section is induced based only upon the main current of the IGBT. Accordingly, the induced electromotive force produced on the coil section is not affected by a current flowing through the flywheel diode (FWD), thereby obtaining further stabilized induced electromotive force.

Moreover, a lead wire at the side of the emitter terminal serving as a reference potential of the gate bias is a gate bias reference wire which is connected between the junction point (referred to as “an emitter auxiliary terminal” hereinbelow) on the main current circuit wire and a gate bias power source terminal. The junction point of the gate bias reference wire and the main current circuit wire is positioned between the winding section of the coil and the emitter terminal of the IGBT on the main current circuit wire.

By this configuration, the reference bias of the gate is not affected by a current flowing through the flywheel diode (FWD), thereby obtaining further stabilized reference bias of the gate, thereby assuredly preventing malfunction of the IGBT in the power module.

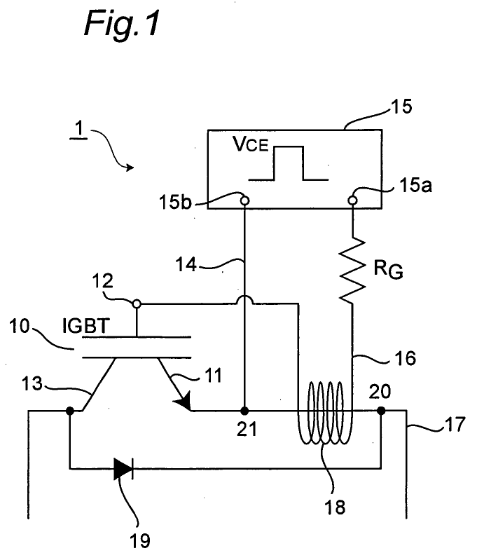

The embodiments of the present invention will be described below with reference to FIGS. 1 to 4. Although the embodiments of the present invention is explained by illustrating the case where an IGBT is used as a power switching device, the present invention is not limited to this. The present invention can be applied to the case where other devices such as MOS transistor or the like is used as a power switching device.

[Embodiment 1]

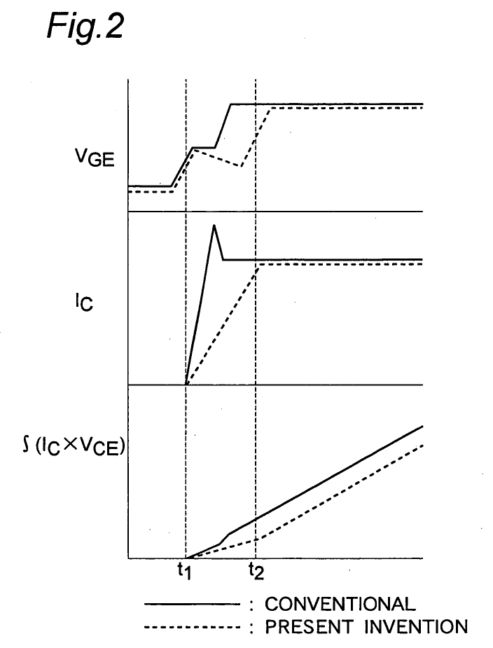

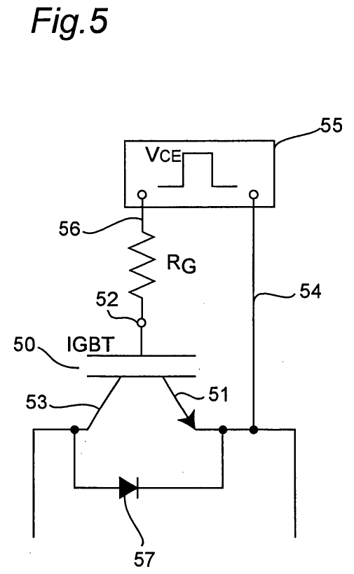

FIG. 1 is a circuit diagram of a gate driving circuit 1 according to the embodiment 1 of the present invention, and FIG. 2 is a waveform chart in which a performance characteristic relating to a time variation is compared between the case of using the gate driving circuit 1 of the embodiment 1 and the case of using the conventional gate driving circuit shown in FIG. 5.

In the gate driving circuit 1 shown in FIG. 1, numeral 10 denotes an IGBT, 11 an emitter terminal (main terminal) of the IGBT 10, 12 a gate terminal, 13 a collector terminal, and 14 a lead wire connecting between an emitter auxiliary terminal 21 that is a junction point at the side of the emitter terminal serving as a reference gate bias and a gate bias power source 15. Numerals 15a and 15b denote gate bias power source terminals, 16 a gate wire including a gate current suppressing resistor R_{G}, 17 a main current circuit wire that is connected between the side of the emitter terminal 11 and an external load (not shown).

A main current supplied from the emitter side flows via the main current circuit wire 17. Numeral 18 denotes a coil section incorporated in the gate wire 16, and 19 a flywheel diode (FWD) connected between the collector terminal 13 and a junction point 20 on the main current circuit wire 17. The junction point 20 on the main current circuit wire 17 is positioned at an outer side (at the side remote from the emitter terminal 11) with respect to the winding position of the coil section 18.

As shown in FIG. 1, in the gate driving circuit 1 according to the embodiment 1, the coil section 18 is incorporated at a predetermined position on the gate wire 16 that applies a bias voltage from the gate bias power source 15 to the gate terminal 12 of the IGBT 10. The coil section 18 is wound around a predetermined portion of the main current circuit wire 17 positioned at the side of the emitter terminal 11 so that the coil section 18 is electrically insulated from the main current circuit wire 17 to cause a mutual induction.

One end of the coil section 18 is connected to the gate terminal 12 of the IGBT, while the other end thereof is connected to the power source terminal 15a of the gate bias power source 15 via the gate driving current suppressing resistor R_{G}.

Thus, the main current circuit wire 17 through which main current flows passes through the central portion of each turn of the coil section 18 so as to be insulated from the coil section, and a value of the induced electromotive force generated in the coil section 18 is in proportion to a value of the main current instantaneously flowing to the external load.

In this configuration, the lead wire 14 positioned on the emitter terminal side serving as the reference gate bias is connected between the power source terminal 15b of the gate bias power source 15 and the emitter auxiliary terminal 21 that is the junction point on the main current circuit wire 17.

In the present embodiment, the junction point (emitter auxiliary terminal) 21 is positioned closer to the side of the emitter terminal 11 of the IGBT with respect to the wire-winding position of the coil section 18 on the main current circuit wire 17. Thus, the reference bias voltage of the gate is further stabilized to thereby obtain an effect of assuredly preventing the malfunction of the IGBT in the power module.

Moreover, the junction point 20 of the cathode side wire of the flywheel diode (FWD) 19 and the main current circuit wire 17 is positioned on the outer side from the winding position of the coil section 18, i.e., at an opposite side to the emitter terminal 11. Therefore, the induced electromotive force produced in the coil section is produced based only on the main current of the IGBT flowing on the main current circuit wire 17, and is not affected by the current flowing through the diode (FWD) 19.

In the above-mentioned configuration, as the coil section 18 provided in the gate wire 16 of the IGBT 10 that applies a gate bias voltage, there may be used a coil that has, for example, four turns, each turn having a diameter of approximately 1 micron, and is covered with an insulating material such as a vinyl or the like.

Thus, by incorporating the coil section 18 into the gate wire 16, the gate bias to be applied to the gate terminal is varied on real time by utilizing the induced electromotive force produced in the coil based upon the main current flowing through the main current circuit wire 17.

The following describes an action of the induced electromotive force produced in the coil section 18 with reference to FIG. 2. The waveform chart in FIG. 2 comparing the performance characteristics shows changes in the waveforms of the main current, gate voltage and the time quadrature (=calorific value) which is a product of a main current and a supply voltage, where a solid line illustrates each waveform in the case of the conventional configuration, while a dot line illustrates each waveform of the configuration of the present invention.

If the induced electromotive force produced on the coil is V_{L}, the emitter current (main current) is i and inductance is L, an equation: V_{L}=L·di/dt is established. A supply voltage V_{CE} supplied by the gate bias power source 15 is a stepwise driving voltage externally applied as a control signal between the gate terminal 12 and the emitter auxiliary terminal 21. The gate bias voltage V_{GE} is a voltage applied from the gate bias power source 15 to the gate terminal 12 of the IGBT via the gate wire 16.

In a switching operation of the IGBT 10, when the main current flowing through the collector terminal 13 and the emitter terminal 11 is varied, the induction electromotive force is induced in the coil section 18 in the gate wire 16 that applies the gate bias. This induced electromotive force serves to moderate a steep rise-up or fall-down gradient of the gate control signal (i.e., gate bias voltage V_{GE}) to be supplied to the gate terminal 12.

In a turning-on operation of the IGBT 10, when the stepwise driving supply voltage V_{CE} steeply rising up is applied between the gate terminal 12 and the emitter auxiliary terminal 21 through the lead wire 14 to start flowing of the collector/emitter current (i.e., main current) i, the induction electromotive force V_{L} is induced in the coil section 18.

This electromotive force V_{L} reversely acts on the driving supply voltage V_{CE}. Therefore, a rising gradient of the gate bias voltage V_{GE} applied to the gate terminal 12 is moderated. In proportion to this moderation in the gate bias voltage, the time variation di/dt of the collector/emitter current (main current) i is suppressed. It is to be noted that, in the turning-off operation, a steep fall-down of the collector/emitter current (main current) i is relaxed by the action reverse to that in the turning-on operation.

By using the gate driving circuit of the present embodiment, in the case where the IGBT 10 is turned on under the condition that the external load is short-circuited to the power modulle, the gate bias V_{GE} is reduced during a period (t1 to t2) when the main current Ic increases to thereby suppress the time variation di/dt of the main current, as apparent from the characteristic comparison shown in FIG. 2, comparing to the case of the conventional example (shown in FIG. 5) which has no coil section in the gate wire.

Accordingly, the time quadrature∫ (Ic×V_{CE}) of the (main current×supply voltage), i.e., calorific value, by 3 microseconds after the start of the on-operation of the IGBT can be suppressed by about 10%. As described above, the present embodiment has an effect of preventing a breakdown and malfunction of the power switching device by suppressing an excessive surge voltage occurring in the power switching device.

Moreover, the variation of the gate bias can be adjusted by adjusting the inductance of the coil according to the number of turns of the coil, whereby the time variation of the main current can be adjusted. Further, in a normal switching system with an inductance load added, the time variation of the main current is reduced and there is no reduction in the gate bias. Therefore, there is no delay in the switching speed or no increase in a loss (turn-on loss) due to the influence of the coil in the on-operation.

As described above, the embodiment 1 of the present invention eliminates the conventional problem that a calorific value calculated as a time quadrature of a product of the main current and supply voltage exceeds the limit of a heat tolerance of the IGBT to lead the IGBT to breakdown in the case where the time variation of the main current is great, for example, when an external load is short-circuited. Consequently, occurrence of a tolerance short-circuit due to an excess surge voltage can be effectively suppressed in the power switching device.

[Embodiment 2]

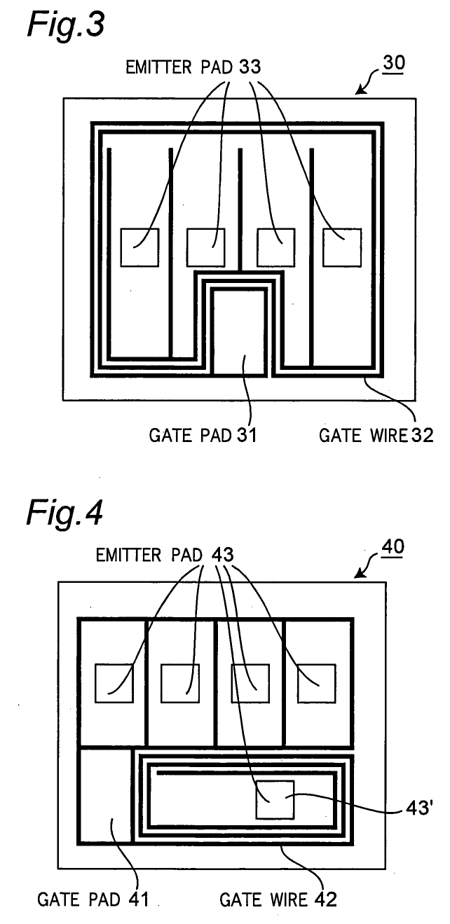

FIG. 3 is a plan view schematically showing a configuration of a gate driving circuit according to an embodiment 2 of the present invention. As shown in FIG. 3, an IGBT chip 30 is provided thereon a gate pad 31 connecting to the gate bias power source, a gate wire 32, and an emitter pad 33 connecting to a circuit wire on the side of the emitter terminal (11) of the IGBT. The emitter pad 33 is divided into plural parts which are arranged in parallel. The gate wire 32 connects the gate pad 31 to the gate terminal 12 (see FIG. 1) of each cell positioned in the IGBT chip.

Further, the gate wire 32 has a coil section 34 arranged such that a portion of the gate wire 32 is wound around the emitter pad 33 in an electrically insulated condition to thereby form an electromotive force inducing section. Specifically, one end of the electromotive force inducing coil section 34 is connected to the gate terminal (12) of the IGBT, while the other end thereof is connected to the gate pad 31.

Moreover, the electromotive force inducing coil section 34 is configured such that it induces the induction electromotive force based only upon the main current of the IGBT when the emitter current (i.e., main current) of the IGBT flows.

Specifically, as explained with reference to FIG. 1 in the embodiment 1, the junction point 20 of the flywheel diode (FWD) 19 of the IGBT and the main current circuit wire 17 is located at an outer side position (opposite to the emitter terminal 11) with respect to the wire-winding position of the coil section 34.

By this arrangement, the induced electromotive force produced on the coil is induced based only on the main current of the IGBT and is not affected by the current flowing through the diode (FWD) 19.

In a preferable embodiment of the gate driving circuit on the IGBT chip 30, a thin-film coil section 34 is provided on the chip and this thin-film coil section 34 is incorporated into a portion of the gate wire 32 that applies a bias voltage to the gate terminal of the IGBT to thereby form the electromotive force inducing section.

This thin-film coil section 34 is wound around the main current circuit wire (17) in an electrically insulated condition therefrom. The main current circuit wire may serve as an emitter current path connected to the side of the emitter electrode. One end of the coil section 34 is connected to the gate terminal 12 of the IGBT, while the other end thereof is connected to the gate pad 31.

When the IGBT chip having the above-mentioned configuration shown in FIG. 3 is turned on with an external load short-circuited, the gate bias is more reduced than the conventional configuration during a period of the main current rising up, as explained in the embodiment 1 with reference to FIG. 2. Thus, the time variation of the main current can be suppressed every IGBT chip.

Accordingly, the short-circuit tolerance in the case of a module having parallel chips mounted thereon can be enhanced. Further, since a normal switching system for an inductance load has reduced a time variation of the main current and has no reduction in the gate bias, there is no delay in the switching speed or no increase in loss (turn-on loss) due to the influence of the coil in the on-operation.

[Embodiment 3]

FIG. 4 is a plan view schematically showing a configuration of a gate driving circuit according to an embodiment 3 of the present invention. The basic configuration of the embodiment 3 is the same as that of the above-mentioned embodiment 2. The different point from the embodiment 2 is that, as shown in FIG. 4, provided on an IGBT chip 40 are a gate pad 41 and a gate wire 42 for connecting the gate pad 41 to a gate terminal of each cell arranged in the IGBT chip.

The gate wire 42 is wound around and insulated from emitter pads 43 that are divided into plural pads which are arranged in parallel, while a portion of the gate wire 42 is formed as a coil section which is wound around another separate emitter pad 43′ in an electrically insulated condition.

Specifically, a portion of the gate wire 42 forms an electromotive force inducing coil section 44 which is electrically insulated around the separate emitter pad 43′ connecting to the emitter terminal (11) of the IGBT. One end of the electromotive force inducing coil section 44 is connected to the gate terminal (12) of the IGBT, while the other end thereof is connected to the gate pad 41.

As explained with reference to FIG. 1 in the above-mentioned embodiment 1, the junction point 20 of the cathode side wire of the flywheel diode (FWD) 19 and the main current circuit wire 17 is positioned at the outer side (opposite side to the emitter terminal 11) with respect to the winding position of the coil section 44. By this configuration, the induction electromotive force produced on the coil section 44 is induced based only on the main current of the IGBT, and is not affected by the current flowing through the diode (FWD) 19.

As described above, the electromotive force inducing coil section 44 is wound around and electrically insulated from the emitter pad 43′ in the gate driving circuit provided on the IGBT chip 40 in this embodiment.

In a preferable embodiment of the gate driving circuit in the IGBT chip 40, a thin-film coil section 44 may be incorporated into a portion of the gate wire 42. This coil section 44 may be wound around the main current circuit wire 17 connected to the side of the emitter electrode in an electrically insulated manner therefrom. One end of the coil section 44 may be connected to the gate terminal 12 of the IGBT, while the other end thereof may be connected to the gate pad 41.

The above configuration allows an optional selection of the time variation of the main current, thereby increasing a degree of freedom when incorporating a coil section. When the IGBT chip having the above-mentioned configuration is turned on with the load short-circuited, the gate bias is more reduced than the conventional configuration during a period of the main current rising up, as shown in FIG. 2, so that the time variation of the main current can be suppressed.

Further, since a normal switching system for an inductance load has reduced a time variation of the main current and has no reduction in the gate bias, there is no delay in the switching speed or no increase in loss (turn-on loss) due to the influence of the coil in the on-operation.

[Embodiment 4]

A gate driving circuit of this embodiment 4 is configured such that, in the configurations of the embodiments 2 and 3, the lead wire 14 (see FIG. 1) located on the side of the emitter terminal serving as a reference gate bias is connected between the power source terminal 15b of the gate bias power source 15 and the emitter auxiliary terminal 21 that is a junction point on the main current circuit wire 17.

The junction point 21 on the main current circuit wire 17 is positioned on the side closer to the emitter terminal of the IGBT with respect to the winding position of the coil section 18 in this embodiment. By this configuration, the reference bias of the gate is further stabilized, thereby being effective of assuredly preventing malfunction of the IGBT in the power module.

As explained with reference to FIG. 1 in the embodiment 1, the junction point 20 on the flywheel diode (FWD) 19 of the IGBT and the main current circuit wire 17 is positioned on the outer side (opposite side to the emitter terminal 11) with respect to the winding position of the coil section. By this configuration, the induction electromotive force produced on the coil is induced based only on the main current of the IGBT, and is not affected by the current flowing through the diode (FWD) 19.

Although the embodiments 1 to 4 illustrate the invention by taking CSTBT as a typical example, the present invention is not limited thereto. The present invention can be also applied to TIGBT, MOSFET, or the like having a trench gate only by changing a design of a masking.

As described above, according to the first aspect of the present invention, a gate bias is controlled by utilizing an electromotive force of a coil section according to a time variation of a main current. Therefore, the time variation of the current can be suppressed on real time when a load is short-circuited. Thus, self-heating of the IGBT can be suppressed at a time of the short-circuit, thereby improving a short-circuit tolerance.

Moreover, since the main current circuit wire is passed through the coil section, an electromotive force produced in the coil is not affected by a distance between the main current circuit wire and the coil, but is determined by the number of turns of the coil and its diameter, thereby obtaining a stabilized electromotive force.

In this configuration, a junction point of a cathode terminal side wire of a flywheel diode and the main current circuit wire is positioned closer to the external load with respect to the winding position of the electromotive force inducing coil section. Thus, the induction electromotive force produced in the coil is induced based only on the main current of the IGBT, and is not affected by a current flowing through the diode (FWD), thereby affording further stabilized electromotive force.

In this first aspect, in the case where a junction point of the gate bias reference wire and the main current circuit wire is positioned closer to the emitter terminal with respect to the winding position of the electromotive force inducing coil section, there can be obtained an effect of assuredly preventing a malfunction of the IGBT in the power module, since the reference bias of the gate is further stabilized.

According to the second aspect of the present invention, a gate driving circuit has an electromotive force inducing section which is formed such that a portion of the gate wire is wound around the emitter pad in an electrically insulated condition, and one end of the electromotive force inducing section is connected to the gate terminal, while the other end thereof is connected to the gate pad. The electromotive force inducing section induces induction electromotive force based only on the main current of the IGBT. Thus, the time variation of the main current can be suppressed every IGBT chip, thereby enhancing a short-circuit tolerance in the case of a module having parallel chips mounted thereon.

In this second aspect, a junction point of a cathode terminal side wire of a flywheel diode and the main current circuit wire is positioned closer to the external load with respect to the position of the emitter pad. Thus, the induction electromotive force produced at the electromotive force inducing section is induced based only on the main current of the IGBT, and is not affected by the current flowing through the diode (FWD), thereby affording further stabilized electromotive force.

Further, in the configuration of the second aspect, the electromotive force inducing section is formed as a coil section which is wound around and electrically insulated from a portion of the emitter pad. Thus, the time variation of the main current can be optionally adjusted, thereby increasing a degree of freedom in incorporating the coil section into the gate wire in a circuit design and circuit production.

Moreover, in the configuration of the second aspect, a junction point of the gate bias reference wire and the main current circuit wire is positioned closer to the emitter terminal with respect to the position of the emitter pad corresponding to the winding position of the gate wire forming the electromotive force inducing section. There can be obtained an effect of assuredly preventing a malfunction of the IGBT in the power module, since the reference bias of the gate is further stabilized.

What is claimed is:

1. A gate driving circuit performing a gate driving control by supplying a bias voltage from a gate bias power source to a gate terminal of a power switching device via a gate wire, comprising:
a main current circuit wire that connects an emitter terminal of the power switching device to an external load; and
an electromotive force inducing coil section formed of a portion of the gate wire which is wound around a part of the main current circuit wire in an electrically insulated condition;
wherein one end of the electromotive force inducing coil section is connected to the gate terminal, while the other end thereof is connected to the gate bias power source via a gate driving current suppressing resistor, wherein the electromotive force inducing coil section induces an induction electromotive force based only on a main current of the power switching device flowing on the main current circuit wire.

2. The gate driving circuit as claimed in claim 1, wherein the power switching device has a flywheel diode connected between a collector and an emitter, and a junction point of a cathode terminal side wire of the flywheel diode and the main current circuit wire is positioned closer to the external load with respect to the winding position of the electromotive force inducing coil section.

3. The gate driving circuit as claimed in claim 1, further comprising a gate bias reference wire that is connected between the gate bias power source and the main current circuit wire on the side of the emitter terminal for serving as a reference of the gate bias, wherein a junction point of the gate bias reference wire and the main current circuit wire is positioned closer to the side of the emitter terminal with respect to the winding position of the electromotive force inducing coil section.

4. A gate driving circuit in a power module mounted on a power switching device chip, comprising:
a gate pad to which a gate wire is connected for supplying a bias voltage from a gate bias power source to a gate terminal of the power switching device;
an emitter pad to which a main current circuit wire is connected for connecting an emitter terminal of the power switching device to an external load; and
an electromotive force inducing section formed of a portion of the gate wire which is wound around the emitter pad in an electrically insulated condition;
wherein one end of the electromotive force inducing section is connected to the gate terminal, while the other end thereof is connected to the gate pad, and the electromotive force inducing section induces the induction electromotive force based only on a main current of the power switching device flowing on the main current circuit wire.

5. The gate driving circuit as claimed in claim 4, wherein the power switching device has a flywheel diode connected between a collector and an emitter, and a junction point of a cathode terminal side wire of the flywheel diode and the main current circuit wire is positioned closer to the external load with respect to the position of the emitter pad.

6. The gate driving circuit as claimed in claim 4., wherein the electromotive force inducing section has a coil section which is wound around a portion of the emitter pad in an electrically insulated condition.

7. The gate driving circuit as claimed in claim 4, further comprising a gate bias reference wire that is connected between the gate bias power source and the main current circuit wire on the side of the emitter terminal serving as a reference of the gate bias, wherein a junction point of the gate bias reference wire and the main current circuit wire is positioned closer to the side of the emitter terminal with respect to the position of the emitter pad that corresponds to the winding position of the gate wire forming the electromotive force inducing section.
